(19) United States
(12) Patent Application Publication
(10) Pub. No.: US 2020/0192510 A1
(43) Pub. Date: Jun. 18, 2020

(54) TOUCH SENSOR ASSEMBLY AND PLANARIZATION TAPE

(71) Applicant: 3M INNOVATIVE PROPERTIES COMPANY, St. Paul, MN (US)

(72) Inventors: Richard Y. Liu, Woodbury, MN (US); Brian D. Pennington, North Oaks, MN (US); Victor Ho, St. Paul, MN (US)

(21) Appl. No.: 16/349,141

(22) PCT Filed: Dec. 4, 2017
(86) PCT No.: PCT/US2017/064411

§ 371 Date: May 10, 2019

Related U.S. Application Data
(60) Provisional application No. 62/433,852, filed on Dec. 14, 2016.

(51) Int. Cl. G06F 3/041; G02F 1/1333; H01L 27/32

(52) U.S. Cl. CPC G06F 3/0412; G02F 1/13338; G02F 2001/133357; G06F 2203/04103; H01L 27/323

(57) ABSTRACT

A planarization tape and a touch sensor assembly including a cover glass, a touch sensor film bonded to the cover glass through an optically clear adhesive layer and the planarization tape releasably bonded to the touch sensor film is described. The planarization tape includes a polymeric substrate and a releasable adhesive layer bonded to the substrate. The substrate has a thickness between 250 micrometers and 5 mm, and the adhesive layer has a thickness between 5 micrometers and 100 micrometers. The adhesive layer may be adapted to releaseably bond to at least one of glass and cyclic olefin polymer film

### BACKGROUND

A display may include a display panel, a cover glass over the display panel, and a touch sensor film between the cover glass and the display panel. The display may be assembled by attaching the touch sensor film to the cover glass such that the touch sensor film is planar, and then attaching the touch sensor film/cover glass to the display panel.

### SUMMARY

In some aspects of the present description, a touch sensor assembly including a cover glass, an optically clear adhesive layer, a touch sensor film bonded to the cover glass through the optically clear adhesive layer, and a planarization tape adjacent the touch sensor film opposite the cover glass is provide. The planarization tape includes a polymeric substrate and a releasable adhesive layer bonded to the substrate and releasably bonded to the touch sensor film. The substrate has a thickness between 250 micrometers and 5 mm, and the releasable adhesive layer has a thickness between 5 micrometers and 100 micrometers.

In some aspects of the present description, a planarization tape including a polymeric substrate and an adhesive layer bonded to the substrate is provided. The substrate has a thickness between 250 micrometers and 5 mm, and a haze of no more than 3 percent. The adhesive layer has a thickness between 5 micrometers and 100 micrometers. The adhesive layer is adapted to releaseably bond to at least one of glass and cyclic olefin polymer film.

### BRIEF DESCRIPTION OF THE DRAWINGS

FIG. 1 is a schematic cross-sectional view of a planarization tape;

FIG. 2 is a schematic cross-sectional view of a touch sensor assembly; and

FIG. 3 is a schematic cross-sectional view of a display device.

### DETAILED DESCRIPTION

In the following description, reference is made to the accompanying drawings that forms a part hereof and in which various embodiments are shown by way of illustration. The drawings are not necessarily to scale. It is to be understood that other embodiments are contemplated and may be made without departing from the scope or spirit of the present description. The following detailed description, therefore, is not to be taken in a limiting sense.

A display may include a touch sensor film which may include a substrate (e.g., a glass substrate or a cyclic olefin polymer (COP) substrate) and may include rows of electrodes on opposing major surfaces of the substrate. The electrodes may be formed from conductive transparent oxides (e.g., indium tin oxide) or from metallic micromesh, for example. Touch sensor films are described in U.S. Pat. No. 9,360,971 (Barton et al.) and in US Pat. Appl. Pub. Nos. 2009/0219257 (Frey et al.) and 2011/0139516 (Nirmal et al.), for example.

A touch sensor film may be incorporated into a display as follows. The touch sensor film may be first laminated to a cover glass for use with the display through an optically clear adhesive. It is typically desired that the touch sensor film is planarized before the touch sensor film/cover glass laminate is applied to the display. A planarization step may be needed, for example, when the cover glass includes a three dimensional structure such as ink steps near the boundary of the cover glass, for example. The planarization can be accomplished by temporarily attaching the touch sensor film/cover glass laminate to an additional substrate to planarize the touch sensor film through the use of heat and/or pressure (for example, placing the touch sensor film/cover glass/additional substrate between two flat heated plates and applying pressure to the plates), and then removing the additional substrate from the touch sensor film and applying the touch sensor/cover glass laminate to the display panel. Once the touch second/cover glass is attached to the additional substrate, it is often desired to inspect the assembly for defects. The inspection can be carried out before and/or after the application of heat and/or pressure. It is typically desired that the substrate have a low haze in order to facilitate this inspection. Inspection may also be carried out at other steps in the process as well. For example, the various assemblies may be inspected for defects following lamination of the touch sensor film to the optically clear adhesive, and/or following lamination of the cover glass/optically clear adhesive to the cover glass. The additional substrate can be a glass with an adhesive layer. However, glass is prone to breaking or cracking unless made with sufficient thickness to prevent this and using thick glass can make it difficult to remove the touch sensor/cover glass assembly from the glass since a thick glass is not flexible enough for easy debonding. Furthermore, it may be desirable that the additional substrate is disposable and a glass substrate may be too expensive to use as a disposable component. According to the present description, it has been found that a tape with a releasable adhesive layer and a thick polymeric substrate (e.g., at least 250 micrometers thick) can be used as the additional substrate. Tapes suitable for use in the planarization process will be referred to herein as planarization tapes.

The planarization tapes of the present description typically includes a polymeric substrate and an adhesive layer bonded to the substrate, where the substrate has a thickness between 250 micrometers and 5 mm, and a haze of no more than of no more than 10 percent (or preferably no more than 5 percent, or more preferably no more than 3 percent, or even more preferably no more than 2 percent), and where the adhesive layer has a thickness between 1 micrometers and 100 micrometers (or preferably between 5 micrometers and 100 micrometers, or even more preferably between 5 micrometers and 50 micrometers). Haze can be determined using a HAZEGARD PLUS haze meter (available from BYK Gardner USA, Columbia, Md.) as specified in the ASTM D1003-13 test standard. The adhesive layer may be a releasable adhesive that it is adapted to releaseably bond to at least one of glass and cyclic olefin polymer film. An adhesive may be said to releasably bond to a substrate or may be described as a releasable adhesive if the adhesive can detach from the substrate via adhesive failure at the interface between the adhesive and the substrate as opposed to detaching through cohesive failure in the bulk of the adhesive which would leave adhesive residue on the substrate.

In some embodiments, the substrate of the planarization tape has a haze of no more than 2 percent or of no more than 1 percent. In some embodiments, the releasable adhesive layer has a haze of no more than 2 percent or of no more than 1 percent. In some embodiments, the touch sensor film has a first refractive index (e.g., the refractive index of a substrate of the touch sensor film such as COP or glass) and the releasable adhesive layer is selected to have a second refractive index similar to the first refractive index. For example, in some embodiments, an absolute value of a difference between the first and second refractive indices is no more than 0.05, or no more than 0.02, or no more than 0.01. In some embodiments, the refractive indices of the releasable adhesive layer and the substrate may also be approximately matched (e.g., to within a refractive index difference of no more than 0.05, or no more than 0.02, or no more than 0.01). Utilizing a low haze substrate, and/or utilizing a low haze releasable adhesive, and/or utilizing a releasable adhesive with a refractive index similar to that of the touch sensor film has been found to aid in inspection of a touch sensor assembly that includes a cover glass, an optically clear adhesive layer, a touch sensor film bond to the cover glass through the optically clear adhesive layer, and a planarization tape adjacent the touch sensor film opposite the cover glass.

It is generally desired that the substrate be sufficiently thick and stiff to provide the needed support in a planarization process, but not to be so thick and stiff that the planarization tape is difficult to remove from the touch panel assembly. In some embodiments, the substrate is at least 250 micrometers thick, or at least 275 micrometers thick, or at least 300 micrometers thick, or at least 350 micrometers thick. In some embodiments, the substrate has a thickness of no more than 2 mm or of no more than 1 mm. In some embodiments, the substrate has a Young's modulus in a range of 0.5 to 10 GPa. Young's modulus refers to the Young's modulus (commonly denoted E) determined at 25° C. except where indicated differently. In some embodiments, the Young's modulus of the substrate is at least 1 GPa, or at least 2 GPa. In some embodiments, the Young's modulus of the substrate is no more than 8 GPa, or no more than 6 GPa. It has been found to be particularly advantageous for achieving the desired balance of rigidity and bendability for the thickness to be in a range of 300 micrometers to 1 mm and for the Young's modulus to be in a range of 2 GPa to 6 GPa.

The substrate may be from any materials that can provide desired mechanical and optical properties. Suitable polymers for use in the substrate include polycarbonate, (meth)acrylic, polyesters, polyetheretherketone (PEEK), polyamide, polyimide, polystyrene, and blends or copolymers thereof. In some embodiments, the substrate includes polyesters. For example, in some embodiments the substrate includes polyethylene terephthalate (PET), and in some embodiments, the substrate includes a copolyester of polyethylene terephthalate and glycol-modified PET (PETG). The substrate may be formed using a film extrusion process, for example. The substrate may optionally be oriented (e.g., uniaxially or biaxially stretched) in order to improve the mechanical properties of the substrate. Useful thick polyester substrates having a low haze are described in U.S. Pat. Appl. Pub. No. 2011/0051040 (Johnson et al.), for example.

In some embodiments, the releasable adhesive layer is a pressure sensitive adhesive (PSA) layer. Pressure sensitive adhesive compositions are well known to those of ordinary skill in the art to possess properties including the following: (1) tack, (2) adherence with no more than finger pressure, (3) sufficient ability to hold onto an adherend, and (4) sufficient cohesive strength to be cleanly removable from the adherend. Materials that have been found to function well as pressure sensitive adhesives are polymers designed and formulated to exhibit the requisite viscoelastic properties resulting in a desired balance of tack, peel adhesion, and shear holding power. Suitable PSAs may be based on crosslinked (meth)acrylics, rubbers, thermoplastic elastomers, silicones, polyurethanes, and the like, and may include tackifiers in order to provide the desired tack. In some embodiments, the PSA is based on a (meth)acrylic PSA or at least one poly(meth)acrylate, where (meth)acrylate refers to both acrylate and methacrylate groups. Acrylic based pressure sensitive adhesives are described in U.S. Pat. No. 4,726,982 (Traynor et al.), for example. Silicone based pressure sensitive adhesives are described in U.S. Pat. No. 6,730,397 (Melancon et al.), for example. Polyurethane based pressure sensitive adhesives are described in U.S. Pat. Appl. Pub. No. 2005/0137375 (Hansen et al.), for example.

In some embodiments, the adhesive layer has a shear storage modulus (commonly denoted G′ (G prime)) in a range of 0.1 to 2 MPa. The shear storage modulus refers to the real part of the complex shear modulus determined using Dynamic Mechanical Analysis (DMA) at 23° C. and 1 Hz unless specified differently. In some embodiments, the releasable adhesive layer has a thickness of no more than 100 micrometers, or no more than 50 micrometers, or no more than 40 micrometers, or no more than 30 micrometers. In some embodiments, the releasable adhesive layer has a thickness of at least 1 micrometer, or at least 5 micrometers, or at least 10 micrometers, or at least 20 micrometers.

In some embodiments, the releasable adhesive layer is optically clear. “Optically clear” refers to an adhesive or article that has a high light transmittance over at least a portion of the visible light spectrum (wavelengths from about 400 nm to about 700 nm), and that exhibits low haze. Optically clear adhesives and articles generally have greater than 90 percent transmittance of visible light and haze values of no more than 5 percent, or no more than 2 percent, or no more than 1 percent. In some embodiments, the releasable adhesive is an optically clear pressure sensitive adhesive.

In some embodiments, the releasable adhesive layer is an olefin block copolymer based adhesive layer, an acrylic based pressure sensitive adhesive, a silicone based pressure sensitive adhesives or a polyurethane based pressure sensitive adhesive. In some embodiments, the releasable adhesive layer includes an olefin block copolymer at no less than 50 weight percent, or no less than 60 weight percent, or no less than 70 weight percent. In some embodiments, the olefin block copolymer includes blocks selected from the group consisting of styrene, ethylene, propylene, isoprene, octene, butylene, butene, and copolymers thereof. In some embodiments, the olefin block copolymer has a chain architecture selected from linear diblock, linear triblock, branched diblock, multiblock, star-shaped multiblock, or branched multiblock copolymers. In some embodiments, the olefin block copolymer based adhesive layer is a pressure sensitive adhesive layer which may be an optically clear pressure sensitive adhesive layer. Olefin block copolymer based pressure sensitive adhesives are described in U.S. Pat. Appl. Pub. No. 2014/0335299 (Wang et al.), for example.

In some embodiments, the releasable adhesive layer is a polyurethane based adhesive layer. In some embodiment, the polyurethane base adhesive comprises a reaction product of a polyol component, a polyisocyanate component, and at least one functional compound.

In some embodiments, the polyurethane based releasable adhesive includes an aromatic and/or aliphatic (e.g. polyester, polycaprolactone, polycarbonate) polyol that comprises at least two hydroxyl terminal groups. When the (e.g. polyester) polyol averages 2 hydroxyl groups, it may be characterized as an (e.g. aromatic polyester) diol. In other embodiments, the (e.g. aromatic polyester) polyol may be characterized as an (e.g. aromatic polyester) triol. In still other embodiments, the (e.g. aromatic polyester) polyol may comprise a mixture of diol and triol, where the number of hydroxyl groups averages greater than 2 and less than 3. Other useful polyols have 4, 5 or 6 hydroxyl terminal groups. Polyester polyols can be obtained, for example, by an esterification reaction between a polyol component and an acid component. Examples of acid components include succinic acid, methylsuccinic acid, adipic acid, pimelic acid, azelaic acid, sebacic acid, 1,12-dodecanedioic acid, 1,14-tetradecanedioic acid, dimer acid, 2-methyl-1,4-cyclohexanedicarboxylic acid, 2-ethyl-1,4-cyclohexanedicarboxylic acid, terephthalic acid, isophthalic acid, phthalic acid, 1,4-naphthalenedicarboxylic acid, 4,4′-biphenyldicarboxylic acid, and acid anhydrides thereof.

In some embodiments, the polyurethane based releasable adhesive includes an aliphatic polyisocyanate component that may include various polyfunctional isocyanate compounds. Examples of such polyfunctional isocyanate compounds include polyfunctional aliphatic isocyanate compounds and polyfunctional aliphatic cyclic isocyanate compounds

In some embodiments, the polyurethane based releasable adhesive includes a polyfunctional aliphatic isocyanate compound that may include trimethylene diisocyanate, tetramethylene diisocyanate, hexamethylene diisocyanate, pentamethylene diisocyanate, 1,2-propylene diisocyanate, 1,3-butylene diisocyanate, dodecamethylene diisocyanate, and 2,4,4-trimethylhexamethylene diisocyanate.

In some embodiments, the polyurethane based releasable adhesive includes a polyfunctional aliphatic cyclic isocyanate compound that may include 1,3-cyclopentene diisocyanate, 1,3-cyclohexane diisocyanate, 1,4-cyclohexane diisocyanate, isophorone diisocyanate, hydrogenated diphenylmethane diisocyanate, hydrogenated xylylene diisocyanate, hydrogenated tolylene diisocyanate, hydrogenated tetramethylxylene diisocyanate, and bio-based polyfunctional aliphatic cyclic isocyanates, such as 2-heptyl-3,4-bis(9-isocyanatononyl)-1-pentylcyclohexane from BASF Corporation under tradename DDI 1410.

In some embodiments, the polyurethane based releasable adhesive includes a polyfunctional aliphatic isocyanate compound that comprises an aliphatic cyclic isocyanate compound, such as isophorone diisocyanate (IPDI), hexamethylene diisocyanate, or mixtures thereof. In other embodiments, the polyfunctional aliphatic isocyanate compound can be mixed with aromatic isocyanate compound, such as 1,4 methylene diphenyl diisocyanate (MDI), m-tetramethylene diisocyanate (TMXDI), or mixtures thereof.

In some embodiments, the polyurethane based releasable adhesive includes an aliphatic polyester polyol (e.g. a caprolactone segment) or an aliphatic polycarbonate polyester polyol with a cyclic aliphatic polyisocyanate. In other embodiments, the polyurethane based releasable adhesive includes an aromatic polyester or a polycarbonate polyol.

In some embodiments, the releasable adhesive is a silicone based pressure sensitive adhesive. In some embodiments, the silicone adhesive includes at least 50 wt. percent (or more preferably at least 70 wt. percent, or most preferably at least 85 wt. percent) polydiorganosiloxane. Suitable polydiorganosiloxanes having the general formula R₁R₂SiO(R₂SiO)ₙSiR₂R₁ and a number average molecular weight of at least 20,000 are commercially available from sources such as Gelest Inc., Tullytown, Pa. Here, R₁ and R₂ represent hydrocarbon groups. Examples are described in U.S. Pat. No. 5,082,706 (Tangney). For particularly preferred embodiments, the number average molecular weight is preferably at least about 50,000, more preferably, at least about 100,000, and most preferably, at least about 250,000.

Other suitable polydiorganosiloxanes have the general formula R₁R₂SiO(R₂SiO)ₘ(R₁RSiO)ₙSiR₂R₁ and a number average molecular weight of less than 20,000 are commercially available from sources such as Gelest Inc. Preferred materials have an alkenyl equivalent weight (as a result of the choice of m and n) of about 250 to about 10,000, more preferably, about 250 to about 5000, and most preferably, about 250 to about 2000.

Some suitable organohydrogenpolysiloxane having an average of at least 2 silicon-bonded hydrogen atoms in each molecule are commercially available from sources such as Dow Corning, Midland, Mich. and General Electric Silicones, Waterford, N.Y. Examples are described in U.S. Pat. No. 5,082,706 (Tangney).

Such silicone adhesives are prepared by addition-cure chemistry and typically involve the use of a platinum or other Group VIIIB (i.e., Groups 8, 9, and 10) metal catalysts, typically, hydrosilation catalysts, to effect the curing of the silicone adhesive. Reported advantages of addition-cured silicone adhesives include reduced viscosity as compared to silicone adhesives prepared via condensation chemistry, higher solids content, stable viscosity with respect to time, and lower temperature cure Methods of preparation are described in U.S. Pat. No. 5,082,706 (Tangney), for example.

In some embodiments, the releasable adhesive is an acrylic based adhesive. Acrylate-type adhesives include one or more polymerizable acrylic monomers. Such acrylic adhesives, are described, for example, in U.S. Pat. No. 5,965,256 (Barrera). Acrylate adhesives are typically copolymers of a major proportion of an acrylic acid ester of a non-tertiary alcohol containing from about 4 to about 14 carbon atoms and a minor portion of at least one modifying polar acrylic-type monomer. Acrylic acid esters useful in adhesives of the multilayered films of the invention may include, but are not limited to n-butyl acrylate, hexyl acrylate, heptyl acrylate, octyl acrylate, isooctyl acrylate, 2-ethylhexyl acrylate, isobornyl acrylate, and combinations thereof. Preferred acrylic acid esters include isooctyl acrylate, 2-ethylhexyl acrylate, isobornyl acrylate, and combinations thereof. Modifying polar acrylic-type monomers may include, but are not limited to, acrylic acid, methacrylic acid, acrylamide, methacrylamide, acrylonitrile, methacrylonitrile, N-vinylpyrrolidone, N-substituted acrylamides such as, hydroxyalkyl acrylates, maleic anhydride, itaconic acid, and combinations thereof. The acrylic adhesive may be crosslinked for increased cohesion and releasability.

In some embodiments, the releasable adhesive layer is capable of being crosslinked (e.g., via the application of actinic radiation or heat) or has been crosslinked. An adhesive may be crosslinked in order to improve mechanical properties (e.g., shear storage modulus) of the adhesive. In some embodiments, the releasable adhesive layer includes a crosslinker. The crosslinker may be a multifunctional acrylate having a functionality greater than 2 that is miscible with the adhesive. Suitable crosslinkers include glycerol propoxylate triacrylate, pentaerythritol tetraacrylate, pentaerythritol triacrylate, trimethylolpropane ethoxylate triacrylate, and alkoxylated derivatives thereof.

In some embodiments, the releasable adhesive layer includes a photoinitiator. Photoinitiators suitable for the preparation of releasable adhesives include acyloin ethers (e.g., benzoin ethyl ether, benzoin isopropyl ether, anisoin ethyl ether and anisoin isopropyl ether), substituted acyloin ethers (e.g., alpha-hydroxymethyl benzoin ethyl ether), Michler's ketone (4,4′-bis[dimethylamino]benzophenone), and the like. A preferred photoinitiator is 2,2-dimethoxy-2-phenyl acetophenone, commercially available as KB-1 from Sartomer Company, Inc., Exton, Pa. Suitable photoinitiators include those available from BASF Corporation (Florham Park, N.J.) under the tradename IRGACURE. For example, the photointiator may be 2,2-Dimethoxy-1,2-diphenylethan-1-one (CAS No. 24650-42-8) which is available from BASF Corporation under the tradename IRGACURE 651. As another example, the photointiator may be 1-Hydroxy-cyclohexyl-phenyl-ketone (CAS No. 947-19-3) which is available from BASF Corporation under the tradename IRGACURE 184.

The releasable adhesive layer may optionally include tackifier at a level sufficient to provide a temporary bond but not enough to provide a permanent bond, although adhesive formulations not utilizing a tackifier may alternatively be used. In some embodiments, the releasable adhesive layer includes tackifier at 1 to 30 weight percent, or at 5 to 25 weight percent, or at 10 to 20 weight percent. In some embodiments, the tackifier is selected from the group consisting of C5 hydrocarbons, C9 hydrocarbons, aliphatic resins, aromatic resins, terpenes, terpenoids, terpene phenolic resins, rosins, rosin esters, and combinations thereof. An adhesive layer including an olefin block copolymer at no less than 60 weight percent, a tackifier in a range of 10 to 20 weight percent and a thickness in a range of 10 to 30 micrometers has been found to be particularly advantageous in providing the desired degree of releasable bonding to a touch sensor film.

The planarization tape can be made, for example, by extruding the substrate of the planarization tape and then coating a releasable adhesive composition onto the substrate to form the releasable adhesive layer. In some embodiments, the substrate is pre-treated prior to coating the releasable adhesive in order to improve the adhesion between the substrate and the adhesive layer. The pre-treatment can include one or more of corona discharge, plasma discharge, flame processing, electron beam irradiation, UV irradiation, acid etching, and chemical primer processing. Such pre-treatment can be performed with or without a reactive chemical adhesion promoter such as hydroxyethyl acrylate or hydroxyethyl methacrylate or other reactive species or primers having a low or medium molecular weight.

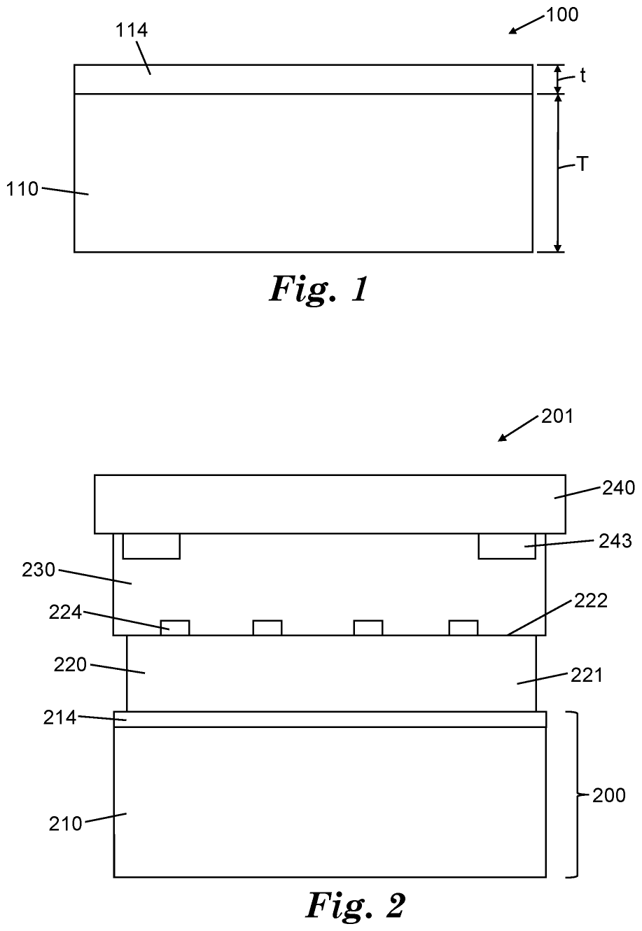

FIG. 1 is a schematic cross-sectional view of planarization tape 100 including a polymeric substrate 110 and an adhesive layer 114 bonded to the substrate 110. The substrate 110 has a thickness T between 250 micrometers and 5 mm or in other ranges described elsewhere herein. In some embodiments, the substrate 110 has a haze of no more than 3 percent, or no more than 2 percent, or even no more than 1 percent. The adhesive layer 114 has a thickness t between 5 micrometers and 100 micrometers or in other ranges described elsewhere herein. The adhesive layer 114 is adapted to releaseably bond to at least one of glass and cyclic olefin polymer film and may be described as a releasable adhesive layer. The substrate 110 and the adhesive layer 114 may be made from materials described elsewhere herein and may have the mechanical properties described elsewhere herein.

FIG. 2 is a schematic cross-sectional view of touch sensor assembly 201 including a cover glass 240, an optically clear adhesive layer 230, a touch sensor film 220 bonded to the cover glass 240 through the optically clear adhesive layer 230, and a planarization tape 200 adjacent the touch sensor film 220 opposite the cover glass 240. The planarization tape 200 includes a polymeric substrate 210 and a releasable adhesive layer 214 bonded to the substrate 210 and releasably bonded to the touch sensor film 220. The planarization tape 200 may correspond to the planarization tape 100. In some embodiments, the substrate has a thickness between 250 micrometers and 5 mm or in other ranges described elsewhere herein, and the releasable adhesive layer has a thickness between 5 micrometers and 100 micrometers or in other ranges described elsewhere herein. The substrate 210 and the adhesive layer 214 may be made from materials described elsewhere herein and may have the mechanical properties described elsewhere herein.

The touch sensor film 220 includes a substrate 221 having a major surface 220 upon which electrodes 224 are disposed. In some embodiments, electrodes 224 are formed from a transparent conductor such as indium tin oxide (ITO) and in some embodiments, electrodes 224 are formed from microwire conductors. In some embodiments, the touch sensor film 220 includes a second layer of electrodes spaced apart from the layer of electrodes 224 illustrated in FIG. 2. In some embodiments, the optically clear adhesive layer 230 covers ink steps 243 and bonds to the cover glass 240 and similarly covers the electrodes 224 and bonds to the major surface 222. The releasable adhesive layer 214 is releasably bonded to touch sensor film 220.

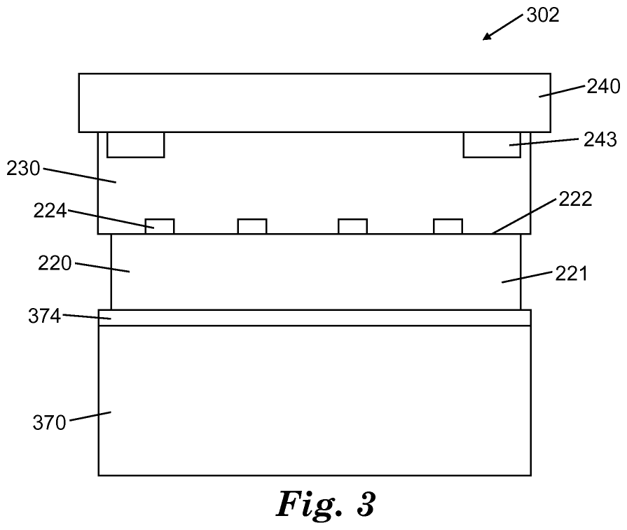

FIG. 3 is a schematic cross-sectional view of display device 302 including the cover glass 240, the optically clear adhesive layer 230, the touch sensor film 220 bonded to the cover glass 240 through the optically clear adhesive layer 230 and bonded to a display panel 370 through an optically clear adhesive layer 374. The display device 302 may be made by providing the touch sensor assembly 201, removing the planarization tape 200 from the touch sensor film 220 and disposing the touch sensor film 220 on display panel 370. In the illustrated embodiment, the touch sensor film 220 is laminated to display panel 370 through optically clear adhesive layer 374. In some embodiments, the display panel 370 is a liquid crystal display (LCD) panel or an organic light emitting diode (OLED) display panel. The OLED display panel may be one or more of a flexible OLED display panel, a bended OLED display panel, a foldable OLED display panel, and a curved OLED display panel. In the case of a flexible OLED display panel, the cover glass may be a flexible cover glass such at the 25 micrometer thick glass available from SCHOTT AF (Mainz, Germany) or the cover glass may be replaced with an alternative protective layer such as a polymer layer with an optional hard coat.

The following is a list of exemplary embodiments of the present description.

Embodiment 1 is a touch sensor assembly comprising:
a cover glass;
an optically clear adhesive layer;
a touch sensor film bonded to the cover glass through the optically clear adhesive layer;
a planarization tape adjacent the touch sensor film opposite the cover glass;
wherein the planarization tape comprises a polymeric substrate and a releasable adhesive layer bonded to the substrate and releasably bonded to the touch sensor film, the substrate has a thickness between 250 micrometers and 5 mm, the releasable adhesive layer has a thickness between 5 micrometers and 100 micrometers.
Embodiment 2 is the touch sensor assembly of Embodiment 1, wherein the substrate has a haze of no more than 3 percent.
Embodiment 3 is the touch sensor assembly of Embodiment 1, wherein the substrate has a haze of no more than 2 percent.
Embodiment 4 is the touch sensor assembly of Embodiment 1, wherein the releasable adhesive layer comprises tackifier at 1 to 30 weight percent.
Embodiment 5 is the touch sensor assembly of Embodiment 4, wherein the tackifier is selected from the group consisting of C5 hydrocarbons, C9 hydrocarbons, aliphatic resins, aromatic resins, terpenes, terpenoids, terpene phenolic resins, rosins, rosin esters, and combinations thereof.
Embodiment 6 is the touch sensor assembly of Embodiment 1, wherein the substrate comprises a polyester.
Embodiment 7 is the touch sensor assembly of Embodiment 6, wherein the substrate comprises polyethylene terephthalate.
Embodiment 8 is the touch sensor assembly of Embodiment 6, wherein the substrate comprises a copolyester of polyethylene terephthalate (PET) and glycol-modified PET (PETG).
Embodiment 9 is the touch sensor assembly of Embodiment 1, wherein the thickness of the substrate is at least 275 micrometers.
Embodiment 10 is the touch sensor assembly of Embodiment 1, wherein the thickness of the substrate is at least 300 micrometers.
Embodiment 11 is the touch sensor assembly of Embodiment 1, wherein the substrate has a Young's modulus in a range of 0.5 to 10 GPa.
Embodiment 12 is the touch sensor assembly of Embodiment 11, wherein the Young's modulus of the substrate is at least 1 GPa.
Embodiment 13 is the touch sensor assembly of Embodiment 11, wherein the Young's modulus of the substrate is at least 2 GPa.
Embodiment 14 is the touch sensor assembly of Embodiment 1, wherein the thickness of the releasable adhesive layer is no more than 50 micrometers.
Embodiment 15 is the touch sensor assembly of Embodiment 1, wherein the thickness of the releasable adhesive layer is no more than 40 micrometers.
Embodiment 16 is the touch sensor assembly of Embodiment 1, wherein the thickness of the releasable adhesive layer is no more than 30 micrometers.
Embodiment 17 is the touch sensor assembly of Embodiment 1, wherein the releasable adhesive layer comprises an olefin block copolymer at no less than 50 weight percent.
Embodiment 18 is the touch sensor assembly of Embodiment 17, wherein the olefin block copolymer comprises blocks selected from the group consisting of styrene, ethylene, propylene, isoprene, octene, butylene, butene, and copolymers thereof.
Embodiment 19 is the touch sensor assembly of Embodiment 17, wherein the olefin block copolymer comprises a chain architecture selected from linear diblock, linear triblock, branched diblock, multiblock, star-shaped multiblock, or branched multiblock copolymers.
Embodiment 20 is the touch sensor assembly of Embodiment 1, wherein the releasable adhesive layer comprises an olefin block copolymer at no less than 60 weight percent.
Embodiment 21 is the touch sensor assembly of Embodiment 1, wherein the releasable adhesive layer comprises an olefin block copolymer at no less than 70 weight percent.
Embodiment 22 is the touch sensor assembly of Embodiment 1, wherein the releasable adhesive layer comprises an acrylic based pressure sensitive adhesive.
Embodiment 23 is the touch sensor assembly of Embodiment 1, wherein the releasable adhesive layer comprises a silicone based pressure sensitive adhesive.
Embodiment 24 is the touch sensor assembly of Embodiment 1, wherein the releasable adhesive layer comprises a polyurethane based pressure sensitive adhesive.
Embodiment 25 is the touch sensor assembly of Embodiment 1, wherein the touch sensor film has a first refractive index, the releasable adhesive layer has a second refractive index, and an absolute value of a difference between the first and second refractive indices is no more than 0.05.
Embodiment 26 is the touch sensor assembly of Embodiment 25, wherein the absolute value of the difference between the first and second refractive indices is no more than 0.01.
Embodiment 27 is the touch sensor assembly of Embodiment 1, wherein the releasable adhesive layer has a haze of no more than 1 percent.
Embodiment 28 is the touch sensor assembly of Embodiment 1, wherein the releasable adhesive layer has a shear storage modulus in a range of 0.1 to 2 MPa.
Embodiment 29 is the touch sensor assembly of Embodiment 1, wherein the releasable adhesive layer comprises a crosslinker.
Embodiment 30 is the touch sensor assembly of Embodiment 1, wherein the releasable adhesive layer comprises a photoinitiator.
Embodiment 31 is the touch sensor assembly of Embodiment 1, wherein the substrate is a polyester substrate having a haze of no more than 3 percent and a Young's modulus in a range of 2 to 6 GPa, wherein the thickness of the substrate is between 300 micrometers and 1 mm, and wherein the releasable adhesive layer comprises an olefin block copolymer at no less than 60 weight percent and a tackifier in a range of 10 to 20 weight percent, and wherein the thickness of the releasable adhesive layer is between 10 micrometers and 30 micrometers.
Embodiment 32 is a method of making a display device, comprising:
providing the touch sensor assembly of Embodiment 1;
removing the planarization tape from the touch sensor film; and
disposing the touch sensor film on a display panel.
Embodiment 33 is the method of Embodiment 32, wherein the display panel is an OLED display panel.
Embodiment 34 is the method of Embodiment 32, wherein the display panel is an LCD display panel.
Embodiment 35 is a planarization tape comprising a polymeric substrate and an adhesive layer bonded to the substrate,
wherein the substrate has a thickness between 250 micrometers and 5 mm, and a haze of no more than 3 percent,
wherein the adhesive layer has a thickness between 5 micrometers and 100 micrometers, and
wherein the adhesive layer is adapted to releaseably bond to at least one of glass and cyclic olefin polymer film.
Embodiment 36 is the planarization tape of Embodiment 35, wherein the substrate has a haze of no more than 2 percent.
Embodiment 37 is the planarization tape of Embodiment 35, wherein the adhesive layer comprises tackifier at 1 to 30 weight percent.
Embodiment 38 is the planarization tape of Embodiment 37, wherein the tackifier is selected from the group consisting of C5 hydrocarbons, C9 hydrocarbons, aliphatic resins, aromatic resins, terpenes, terpenoids, terpene phenolic resins, rosins, rosin esters, and combinations thereof.
Embodiment 39 is the planarization tape of Embodiment 35, wherein the substrate comprises a polyester.
Embodiment 40 is the planarization tape of Embodiment 39, wherein the substrate comprises polyethylene terephthalate.
Embodiment 41 is the planarization tape of Embodiment 39, wherein the substrate comprises a copolyester of polyethylene terephthalate (PET) and glycol-modified PET (PETG).
Embodiment 42 is the planarization tape of Embodiment 35, wherein the thickness of the substrate is at least 275 micrometers.
Embodiment 43 is the planarization tape of Embodiment 35, wherein the thickness of the substrate is at least 300 micrometers.
Embodiment 44 is the planarization tape of Embodiment 35, wherein the substrate has a Young's modulus in a range of 0.5 to 10 GPa.
Embodiment 45 is the planarization tape of Embodiment 44, wherein the Young's modulus of the substrate is at least 1 GPa.
Embodiment 46 is the planarization tape of Embodiment 44, wherein the Young's modulus of the substrate is at least 2 GPa.
Embodiment 47 is the planarization tape of Embodiment 35, wherein the thickness of the adhesive layer is no more than 50 micrometers.
Embodiment 48 is the planarization tape of Embodiment 35, wherein the thickness of the adhesive layer is no more than 40 micrometers.
Embodiment 49 is the planarization tape of Embodiment 35, wherein the thickness of the adhesive layer is no more than 30 micrometers.
Embodiment 50 is the planarization tape of Embodiment 35, wherein the adhesive layer has a haze of no more than 1 percent.
Embodiment 51 is the planarization tape of Embodiment 35, wherein the adhesive layer has a shear storage modulus in a range of 0.1 to 2 MPa.
Embodiment 52 is the planarization tape of Embodiment 35, wherein the adhesive layer comprises an olefin block copolymer at no less than 50 weight percent.
Embodiment 53 is the planarization tape of Embodiment 52, wherein the olefin block copolymer comprises blocks selected from the group consisting of styrene, ethylene, propylene, isoprene, octene, butylene, butene, and copolymers thereof.
Embodiment 54 is the planarization tape of Embodiment 52, wherein the olefin block copolymer comprises a chain architecture selected from linear diblock, linear triblock, branched diblock, multiblock, star-shaped multiblock, or branched multiblock copolymers.
Embodiment 55 is the planarization tape of Embodiment 52, wherein the adhesive layer comprises the olefin block copolymer at no less than 60 weight percent.
Embodiment 56 is the planarization tape of Embodiment 52, wherein the adhesive layer comprises the olefin block copolymer at no less than 70 weight percent.
Embodiment 57 is the planarization tape of Embodiment 35, wherein the adhesive layer comprises an acrylic based pressure sensitive adhesive.
Embodiment 58 is the planarization tape of Embodiment 35, wherein the adhesive layer comprises a silicone based pressure sensitive adhesive.
Embodiment 59 is the planarization tape of Embodiment 35, wherein the releasable adhesive layer comprises a polyurethane based pressure sensitive adhesive.
Embodiment 60 is the planarization tape of Embodiment 35, wherein the adhesive layer comprises a crosslinker.
Embodiment 61 is the planarization tape of Embodiment 35, wherein the adhesive layer comprises a photoinitiator.
Embodiment 62 is the planarization tape of Embodiment 35, wherein the substrate is a polyester substrate having a Young's modulus in a range of 2 to 6 GPa, wherein the thickness of the substrate is between 300 micrometers and 1 mm, and wherein the adhesive layer comprises an olefin block copolymer at no less than 60 weight percent and a tackifier in a range of 10 to 20 weight percent, and wherein the thickness of the adhesive layer is between 10 micrometers and 30 micrometers.
Embodiment 63 is the planarization tape of Embodiment 62, wherein the haze of the substrate is no more than 2 percent and the adhesive layer has a haze of no more than 1 percent.
Embodiment 64 is a method of making a display device, comprising:
providing a touch sensor assembly comprising a touch sensor film releasably bonded to the planarization tape of Embodiment 35;
removing the planarization tape from the touch sensor film; and disposing the touch sensor film on a display panel.
Embodiment 65 is the method of Embodiment 64, wherein the display panel is an OLED display panel.
Embodiment 66 is the method of Embodiment 64, wherein the display panel is an LCD display panel.

### EXAMPLES

### Materials Used:

PET: Polyethylene terephthalate (PET) was obtained in pellet form from Nan Ya Plastics Corporation (Taipei, Taiwan) and was designated by the product grade 1N502.

PETg: Glycol-modified polyethylene terephthalate polyester (PETg) was obtained from Eastman Chemical Company (Kingsport, Tenn.) and was designated by the product grade EASTAR GN071 Copolyester.

KRATON D1161: A Styrene-Isoprene-Stryene block copolymer, is commercially available and was obtained from Kraton Performance Polymers LLC (Houton, Tex.).

TMPTA: Trimethylolpropane triacrylate, is commercially available and was obtained from Arkema (Colombes, France) and was designated by the product grade SR351H.

RE100L: A rosin ester tackifier, is commercially available and was obtained from Arizona Chemical, a Division of Kraton Corp. (Jackonville, Fla.), and was designated by the trade name SYLVALITE RE 100L.

IRGACURE 651: A photoinitiator formerly known as CIBA IRGACURE 651 and believed to consist essentially of 2,2-Dimethoxy-1,2-diphenylethan-1-one, is commercially available from BASF Schweiz AG (Basel, Switzerland)

COP: Cyclic Olefin Polymer (COP) was obtained in film form from Zeon Corporation (Tokyo, Japan) and was designated by the product grade ZEONORFILM ZF-16.

### Test Methods:

Tensile Properties:

Films were tested on an INSTRON Tensile Tester Model 5500R (Norwood, Mass., USA), using a test method similar to ASTM D882-Standard Test Method for Tensile Properties of Thin Plastic Sheeting except for any differences described in the following. A 25.4 mm wide film sample was stretched under the conditions of a testing distance of 50.8 mm and a pulling speed of 4.23 mm/s. Young's modulus and tensile strength were obtained from the stress-strain curve. The measurement was performed in an atmosphere of 25° C. and 65% relative humidity.

Haze Test:

Haze was measured according to ASTM D1003-61 using a haze measuring device (available from BYK Gardner under the trade designation “HAZEGARD PLUS”, BYK Gardner catalog number 4725).

Shrinkage Test:

Shrinkage was tested in a convection oven capable of maintaining a target temperature within 2° C. was used with a set temperature of 85° C. and 150° C. Sample strips of 2.54 cm wide and 30 cm long were used. Two marks of 25.4 cm apart are drawn on the film to define the initial length (L0). Samples were hung in the oven for 15 minutes. The final length between to the two marks was measured (Lt). Shrinkage was calculated as follows:

$$Shrinkage , \% = \frac{( {L}_{0} - {L}_{t} )}{{L}_{0}} \times 100 \%$$

180 Degree Peel Adhesion:

Adhesive samples were prepared by solvent casting the adhesive on a release liner at about 25 micrometers thickness followed by drying and curing. The prepared adhesive was then cut into test strips of 25.4 mm×50 mm in dimension for each formulation. Two replicates were prepared for each Example. The adhesive was removed from the release liner, then one of the two exposed adhesive surfaces was adhered along the length of a target substrate surface and the other exposed surface was adhered to a 50 micrometer primed PET film (commercially available from DuPont Teijin Films under the grade of MELINEX 329-200) surface of 25.4 mm×127 mm. Three substrates were used: stainless steel, glass, and COP. The final assembly was rolled down 5 times using a 2.0 kg rubber roller. The substrate was cleaned prior to applying the tape by wiping with acetone once then with heptane three times using a tissue paper. After being conditioned for 72 hrs at 50% relative humidity (RH) at room temperature (RT), the peel adhesion strength was evaluated using a tensile tester (MTS INSIGHT, available from MTS Systems Corporation, Eden Prairie, Minn.), equipped with a 1000 N load cell, using a crosshead speed of 300 mm/min, at an angle of 180° with the test specimen held in the bottom clamp and the tail in the top clamp. The average of two test specimens was reported in grams/25 mm.

Static Shear:

The static shear strength of an adhesive was determined according to ASTMD3654/D3654M-06 except for any differences described in the following. A 500 grams load inside an oven set at 23° C. was used. A test specimen was prepared by laminating a 2.5 cm×2.5 cm piece of adhesive tape in between a stainless steel (SS) panel and a 50 micrometer primed PET film (commercially available from DuPont Teijin Films under the grade of MELINEX 329-200). The time to failure, i.e., the time for the weight to pull the adhesive away from the panel, in minutes, was recorded. If no failure was observed after 10,000 minutes, the test was stopped and a value of 10,000 minutes was recorded.

Gel Fraction Test:

Gel Fraction was determined according to ASTM D 3616-95 except for any differences described in the following. A test specimen containing approximately 0.08 g of adhesive tape was cut from the tape and placed within a 120-mesh stainless steel basket measuring approximately 5 cm×10 cm. The contents were weighed to within 0.1 mg and immersed in a metal pan containing a sufficient amount of tetrahydrofuran to cover the specimen. After extraction for approximately 24 hours, the pouch (containing the remaining specimen) was removed and placed under vacuum to remove residual solvent. The pouch was weighed and the gel content was determined by:

$$Gel content \% = ( 1 - \frac{weight lost during extraction}{weight of original specimen} ) \times 100 \%$$

At least two specimens were measured for gel content and the values reported represent the average of specimens.

### Example 1: 355 Micrometer Clear Substrate (355CS)

On a melt extrusion line, one twin screw extruder was used. The extruder was connected to a film die. The extruder had two resin feeders. One feeder delivered PETg resin at 400 kg/hr. The other feeder delivered PET resin at 1600 kg/hr. The melt line temperature was set at 274° C. and the screw speed was set at 300 rpm. PET and PETg were thus mixed, melted, and pumped to the film die. The single layer melt from the film die was cast onto a chill roll, and the line speed was adjusted to control the cast thickness. The cast film was then sent through a length orienter and then through a tenter stretcher, in order to stretch the film in the machine direction and transverse direction, respectively. The draw ratios were 3.5 for machine direction in length orienter and 3.7 for transverse direction in the tenter. The stretching temperature was set at 95° C. and stretching rate was about 50%/second. Heat setting was done in the tenter with the temperature set at 225° C. for about 15 seconds. The overall cast speed was adjusted so that the final film thickness was 355 micrometers.

The resulting film substrate had Young's modulus of 3 GPa, haze of 0.5%, tensile strength of 385 lbf, 85° C./15 min shrinkage of 0.25% (MD) and 0.15% (TD) and 150° C./15 min shrinkage of 1.7% (MD) and 0.5% (TD).

### Examples 2-7: Planarization Tapes

The coating solutions were made by dissolving the individual raw materials in MEK solvent at solids content of about 15-19% and were mixed for 48 hrs until a homogenous solution was obtained.

Then the solution was coated on the 355 micrometer clear substrate from Example 1 using a Meyer Rod coating technique. The coated specimen was then dried in an oven at 80° C. for about 15 min. The final dried thickness was controlled to be around 25 micrometers by selecting proper Meyer rod size. The dried sample was then cured using a benchtop FUSION UV unit (Heraeus, Gaithersberg, Md.) equipped with a “D” bulb lamp at a UVA dosage of about 2000 MJ/cm² intensity.

The bonding layer compositions of Examples 2-7 are summarized in Table 1. Testing was performed on the specimens of Examples 2-7, and the results are reported in Table 2. In each of Examples 2-7, the static shear and shear creep at 23° C. with a 500 g load was recorded as 10,000 min and 0 mm, respectively. In each of Examples 2-7, the planarization tape was able to be cleanly removed from a COP surface.

TABLE 1
Compositions of Examples 2-7

| | | | | | | Nominal |
|---|---|---|---|---|---|---|
| | KRATON | | | IRGACURE | | Thick. |
| Example | D1161 | TMPTA | RE100L | 651 | Substrate | (micrometers) |
| Ex. 2 | 84% | 4% | 10% | 2% | 355CS | 25 |
| Ex. 3 | 80% | 8% | 10% | 2% | 355CS | 25 |
| Ex. 4 | 76% | 12% | 10% | 2% | 355CS | 25 |
| Ex. 5 | 74% | 4% | 20% | 2% | 355CS | 25 |
| Ex. 6 | 70% | 8% | 20% | 2% | 355CS | 25 |
| Ex. 7 | 66% | 12% | 20% | 2% | 355CS | 25 |

TABLE 2
Test Results for Examples 2-7

| | | 180 Peel | 180 Peel | 180 Peel | |
|---|---|---|---|---|---|
| | Thickness | SS | Glass | COP | |
| Example | (micrometers) | (g/25 mm) | (g/25 mm) | (g/25 mm) | Gel % |
| Ex. 2 | 25 | 347 | 86 | 840 | 87% |
| Ex. 3 | 25 | 111 | 13 | 270 | 86% |
| Ex. 5 | 25 | n/a | n/a | n/a | 75% |
| Ex. 6 | 25 | 275 | 153 | 1127 | 75% |
| Ex. 7 | 25 | 13 | 13 | 26 | 85% |

### Example 8: Planarization Tape on a Touch Sensor with Pre-Mask

A pre-assembled stack of a Cover Glass, an Optically Clear Adhesive (OCA), and a Touch Sensor was used in this Example. The pre-assembled stack also had a protective premask film attached on the touch sensor side. Planarization Tape of Example of 2 was then laminated to the protective pre-mask film surface at ambient temperature at about 0.5 MPa pressure for about 30 seconds. The resulting laminate was then allowed to stand undisturbed at room temperature for about 30 minutes. The Planarization Tape adhered adequately on the premask film and planarized the stack under pressure due to the hard surface of the PT substrate. After the 30 minute dwell time, the Planarization Tape was removed by gently peeling it off of the pre-mask surface. There was no residual adhesive left behind on the pre-mask surface.

### Example 9: Planarization Tape on a Touch Sensor without Pre-Mask

A pre-assembled stack of a Cover Glass, an OCA, and a Touch Sensor was used in this Example. The pre-assembled stack also had a protective premask film attached on the touch sensor side. The protective premask film was first removed from the stack to expose the touch sensor surface. Planarization tape of Example of 2 was then laminated to the touch sensor surface at ambient temperature at about 0.5 MPa pressure for about 30 seconds. The resulting laminate was then allowed to stand undisturbed at room temperature for about 30 minutes. The Planarization Tape adhered adequately on the touch sensor film surface and planarized the stack under pressure due to the hard surface of the Planarization Tape substrate. After the 30 minute dwell time, the Planarization Tape was removed by gently peeling it off of the touch sensor film surface. There was no residual adhesive left behind on the touch sensor surface.

### Example 10: Planarization Tape with a Polyurethane (PU) Adhesive on a Touch Sensor

A pre-assembled stack of a Cover Glass, an OCA, and a Touch Sensor was used in this Example. The pre-assembled stack also had a protective premask film attached on the touch sensor side. The protective premask film was first removed from the stack to expose the touch sensor surface. A planarization tape of a laminated structure which includes the substrate of Example 1, an Optically Clear Adhesive (3M OCA 8171, commercially available from 3M Company, St. Paul, Minn.), and a PU adhesive coated tape (3M 87332 tape, commercially available from 3M Company). The OCA 8171 was positioned in between the substrate of Example 1 and the 87332 tape. The overall thickness of the laminated planarization tape was 440 micrometers. The PU adhesive side of the laminated planarization tape was then laminated to the touch sensor surface at ambient temperature at about 0.5 MPa pressure for about 30 seconds. The resulting laminate was then allowed to stand undisturbed at room temperature for about 30 minutes. The Planarization Tape adhered adequately on the touch sensor film surface and planarized the stack under pressure due to the hard surface of the Planarization Tape substrate. After the 30 minute dwell time, the Planarization Tape was removed by gently peeling it off of the touch sensor film surface. There was no residual adhesive left behind on the touch sensor surface.

### Example 11: Planarization Tape with a Silicone Adhesive on a Touch Sensor

A pre-assembled stack of a Cover Glass, an OCA, and a Touch Sensor was used in this Example. The pre-assembled stack also had a protective premask film attached on the touch sensor side. The protective premask film was first removed from the stack to expose the touch sensor surface. A planarization tape of a laminated structure which includes the substrate of Example 1, an Optically Clear Adhesive (3M OCA 8171, commercially available from 3M Company), and a silicone adhesive coated tape (3M 87250 tape, commercially available from 3M Company). The OCA 8171 was positioned in between the substrate of Example 1 and the 87250 tape. The overall thickness of the laminated planarization tape was approximately 440 micrometers. The silicone adhesive side of the laminated planarization tape was then laminated to the touch sensor surface at ambient temperature at about 0.5 MPa pressure for about 30 seconds. The resulting laminate was then allowed to stand undisturbed at room temperature for about 30 minutes. The Planarization Tape adhered adequately on the touch sensor film surface and planarized the stack under pressure due to the hard surface of the Planarization Tape substrate. After the 30 minute dwell time, the Planarization Tape was removed by gently peeling it off of the touch sensor film surface. There was no residual adhesive left behind on the touch sensor surface.

Descriptions for elements in figures should be understood to apply equally to corresponding elements in other figures, unless indicated otherwise. Although specific embodiments have been illustrated and described herein, it will be appreciated by those of ordinary skill in the art that a variety of alternate and/or equivalent implementations can be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

What is claimed is:

1. A touch sensor assembly comprising:
a cover glass;
an optically clear adhesive layer;
a touch sensor film bonded to the cover glass through the optically clear adhesive layer;
a planarization tape adjacent the touch sensor film opposite the cover glass;
wherein the planarization tape comprises a polymeric substrate and a releasable adhesive layer bonded to the substrate and releasably bonded to the touch sensor film, the substrate has a thickness between 250 micrometers and 5 mm, the releasable adhesive layer has a thickness between 5 micrometers and 100 micrometers.

2. The touch sensor assembly of claim 1, wherein the substrate has a haze of no more than 3 percent.

3. The touch sensor assembly of claim 1, wherein the releasable adhesive layer comprises tackifier at 1 to 30 weight percent.

4. The touch sensor assembly of claim 3, wherein the tackifier is selected from the group consisting of C5 hydrocarbons, C9 hydrocarbons, aliphatic resins, aromatic resins, terpenes, terpenoids, terpene phenolic resins, rosins, rosin esters, and combinations thereof.

5. The touch sensor assembly of claim 1, wherein the thickness of the substrate is at least 275 micrometers.

6. The touch sensor assembly of claim 1, wherein the substrate has a Young's modulus in a range of 0.5 to 10 GPa.

7. The touch sensor assembly of claim 1, wherein the releasable adhesive layer comprises an olefin block copolymer at no less than 50 weight percent.

8. The touch sensor assembly of claim 1, wherein the touch sensor film has a first refractive index, the releasable adhesive layer has a second refractive index, and an absolute value of a difference between the first and second refractive indices is no more than 0.05.

9. The touch sensor assembly of claim 1, wherein the substrate is a polyester substrate having a haze of no more than 3 percent and a Young's modulus in a range of 2 to 6 GPa, wherein the thickness of the substrate is between 300 micrometers and 1 mm, and wherein the releasable adhesive layer comprises an olefin block copolymer at no less than 60 weight percent and a tackifier in a range of 10 to 20 weight percent, and wherein the thickness of the releasable adhesive layer is between 10 micrometers and 30 micrometers.

10. A method of making a display device, comprising:
providing the touch sensor assembly of claim 1;
removing the planarization tape from the touch sensor film; and
disposing the touch sensor film on a display panel.

11. A planarization tape comprising a polymeric substrate and an adhesive layer bonded to the substrate,
wherein the substrate has a thickness between 250 micrometers and 5 mm, and a haze of no more than 3 percent,
wherein the adhesive layer has a thickness between 5 micrometers and 100 micrometers, and
wherein the adhesive layer is adapted to releaseably bond to at least one of glass and cyclic olefin polymer film.

12. The planarization tape of claim 11, wherein the haze of the substrate is no more than 2 percent.

13. The planarization tape of claim 11, wherein the adhesive layer comprises tackifier at 1 to 30 weight percent.

14. The planarization tape of claim 13, wherein the tackifier is selected from the group consisting of C5 hydrocarbons, C9 hydrocarbons, aliphatic resins, aromatic resins, terpenes, terpenoids, terpene phenolic resins, rosins, rosin esters, and combinations thereof.

15. The planarization tape of claim 11, wherein the substrate is a polyester substrate having a Young's modulus in a range of 2 to 6 GPa, wherein the thickness of the substrate is between 300 micrometers and 1 mm, and wherein the adhesive layer comprises an olefin block copolymer at no less than 60 weight percent and a tackifier in a range of 10 to 20 weight percent, and wherein the thickness of the adhesive layer is between 10 micrometers and 30 micrometers.

16. The planarization tape of claim 15, wherein the haze of the substrate is no more than 2 percent and the adhesive layer has a haze of no more than 1 percent.

17. A method of making a display device, comprising:
providing a touch sensor assembly comprising a touch sensor film releasably bonded to the planarization tape of claim 11;
removing the planarization tape from the touch sensor film; and
disposing the touch sensor film on a display panel.
